(19) United States
(12) Patent Application Publication
(10) Pub. No.: US 2026/0231348 A1
(43) Pub. Date: Aug. 6, 2026

(54) ADJUSTABLE PARTITIONING DEVICE AND METHOD FOR A COMPUTING SYSTEM

(71) Applicant: Quanta Computer Inc., Taoyuan City (TW)

(72) Inventors: Yaw-Tzorng TSORNG, Taoyuan City (TW); Ming-Lung WANG, Taoyuan City (TW); Nan-Chun WU, Taoyuan City (TW); Liang-Ju LIN, Taoyuan City (TW)

(21) Appl. No.: 19/046,580

(22) Filed: Feb. 6, 2025

(51) Int. Cl. H05K 7/14

(52) U.S. Cl. CPC H05K 7/1489

(57) ABSTRACT

An adjustable partitioning device and method for a computing system include a chassis that has a chassis compartment defined in part by a chassis cover and a chassis base. The chassis has a plurality of slots disposed in one or more of the chassis cover and the chassis base. An adjustable partition is movably mounted between the chassis cover and the chassis base to separate the chassis compartment into sub-compartments. The adjustable partition has a plurality of hinges. The plurality of hinges is designed to slidably change position within respective ones of the plurality of slots when the adjustable partition is moved between a first position and a second position. Accordingly, the sub-compartments each have a different size in the first position than in the second position, thus efficiently receiving and accommodating computing devices or components having different sizes.

### FIELD OF THE INVENTION

The present invention relates generally to a computing system, and more specifically, to a device and method for adjustably partitioning compartments of a chassis in a computing system to efficiently accommodate components having variable sizes.

### BACKGROUND OF THE INVENTION

Modern computing applications are highly efficient and complex, and require computing systems to have substantial speed and capacity. These computing systems normally employ computing devices, such as servers, in large numbers for high demand applications such as network-based systems or data centers. The emergence of the cloud for computing applications has increased the demand for data centers. Data centers have numerous servers that store data and run applications accessed by remotely connected computer device users. A typical data center has physical chassis structures with attendant power and communication connections. Each chassis holds multiple computing servers and storage servers.

Most computing servers and storage servers employ a design that is easy for installation in and removal from a chassis. Even though they have variable sizes, these servers can be inserted to spaces of compartments of a chassis. A conventional chassis uses a partition, e.g., a bracket or panel, to separate a compartment of the chassis into sub-compartments with the same or different sizes depending on the sizes of the servers to be installed. This partition may be a fixed partition or difficult to be adjusted to fit servers with different sizes. Thus, significant amounts of downtime may be caused by making changes to such a partitioning to switch servers in and out of the chassis. Accordingly, an efficient and effective partitioning device and/or method is critical to improve the operations of a computing system.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, an adjustable partitioning device for a computing system includes a chassis that has a chassis compartment defined in part by a chassis cover and a chassis base. The chassis further has a plurality of slots disposed in the chassis cover, or the chassis base, or both. An adjustable partition of the adjustable partitioning device is movably mounted between the chassis cover and the chassis base. The adjustable partition separates the chassis compartment into sub-compartments. Moreover, the adjustable partition has a plurality of hinges. The plurality of hinges is designed to slidably change position within respective ones of the plurality of slots when the adjustable partition is moved between a first position and a second position. Accordingly, the sub-compartments each have a different size in the first position than in the second position.

According to one aspect of the present disclosure, in the adjustable partitioning device, each of the plurality of slots is defined by a channel extending between a first end and a second end. The first end corresponds to the first position and the second end to the second position.

According to a configuration of the above implementation, each hinge of the plurality of hinges is configured to slide between the first end and the second end within the channel.

According to another configuration of the above implementation, each of the first end and the second end is oriented angularly relative to the channel.

According to yet another configuration of the above implementation, at least one slot of the plurality of slots has a U-shape.

According to a further configuration of the above implementation, the channel has an intermediate end that is proximately positioned on the channel. Each hinge of the plurality of hinges being slidably positioned on the intermediate end.

According to a further aspect of the above implementation, each of the plurality of hinges is a pushpin that is configured to releasably lock in each of the first end and the second end.

According to another configuration of the above implementation, the adjustable partition is releasably secured to the chassis cover via one or more fasteners.

According to another aspect of the present disclosure, a computing system includes a chassis and an adjustable partition. The chassis has a plurality of slots and a chassis compartment. The chassis compartment is divided into sub-compartments that include a first sub-compartment. The first sub-compartment has a first size in a first position to receive a first computing device. Additionally, the adjustable partition is movably mounted within the chassis compartment as a divider between the sub-compartments. The adjustable partition has a plurality of hinges that slidably mount to and change position within the respective ones of the plurality of slots. Further, the adjustable partition is movable between the first position and a second position. The first sub-compartment has a second size in the second position to receive a second computing device that has a different size than the first computing device.

According to a configuration of the above implementation, the chassis includes a chassis cover and a chassis base. The chassis cover and the chassis base define, at least in part, the chassis compartment.

According to another configuration of the above implementation, the plurality of slots is positioned on either the chassis cover or the chassis base, or both.

According to yet another configuration of the above implementation, each slot of the plurality of slots has a channel extending between a first end and a second end. The first end corresponds to the first position and the second end to the second position.

According to a further configuration of the above implementation, each hinge of the plurality of hinges is configured to slide between the first end and the second end within the channel.

According to yet another aspect of the above implementation, the channel has an intermediate end that is proximately positioned on the channel. Moreover, each of the plurality of hinges is slidably positioned on the intermediate end.

According to yet another aspect of the present disclosure, a method is provided for flexibly partitioning a chassis of a computing system. The method includes disengaging one or more fasteners to release an adjustable partition from a chassis cover of the chassis. The chassis further includes a chassis base. Moreover, the chassis cover and the chassis base partially define a chassis compartment. Further, the adjustable partition is movably mounted between the chassis cover and the chassis base to separate the chassis compartment into sub-compartments. The method also includes sliding the adjustable partition from a first position to a second position so that the sub-compartments each have a different size in the first position than in the second position. The method further includes securing the adjustable partition to the chassis cover using the one or more fasteners.

According to a configuration of the above implementation, the method further includes sliding a plurality of hinges within the respective ones of a plurality of slots that is positioned in one or more of the chassis cover and the chassis base. The plurality of hinges is mounted on the adjustable partition. Moreover, the plurality of hinges slidably changes positions within the respective ones of the plurality of slots. Further, each of the plurality of slots has a first end and a second end that define the first position and the second position of the adjustable partition, respectively.

According to another configuration of the above implementation, the method further includes sliding the adjustable partition to an intermediate position via the plurality of hinges. The intermediate position is defined by one or more intermediate ends positioned on each of the plurality of slots between the first end and the second end.

According to yet another configuration of the above implementation, the method includes sliding the plurality of hinges from the first end to the second end along a channel of the plurality of slots. The first end and the second end each is positioned on and angularly oriented relative to the channel.

According to a further configuration of the above implementation, the method includes unlocking each of the plurality of hinges from the first end. Each of the plurality of hinges is a pushpin configured to releasably lock in each of the first end and the second end.

According to yet a further configuration of the above implementation, the method includes locking each of the plurality of hinges in the second end by the pushpin.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an isometric perspective view showing a chassis of a computing system with an adjustable partition installed inside the chassis and positioned at a first position, according to certain aspects of the present disclosure.

FIG. 2 is a sectional perspective view of a section A illustrated in FIG. 1 showing the adjustable partition and a plurality of slots positioned on the chassis, according to certain aspects of the present disclosure.

FIG. 3 is a sectional perspective view of a section B illustrated in FIG. 1 showing that the adjustable partition is releasably attached to a chassis cover of the chassis using one or more fasteners, according to certain aspects of the present disclosure.

FIG. 4 is an exploded perspective view of the chassis of the computing system, according to certain aspects of the present disclosure.

FIG. 5 is an isometric perspective view showing a chassis of a computing system with an adjustable partition installed inside a chassis and positioned at a second position, according to certain aspects of the present disclosure.

FIG. 6 is a sectional perspective view of a section C illustrated in FIG. 5 showing the adjustable partition installed inside the chassis and positioned at the second position, according to certain aspects of the present disclosure.

FIG. 7 is a front view of a chassis of a computing system showing an adjustable partition installed inside the chassis and positioned at an intermediate position between a first position and a second position, according to certain aspects of the present disclosure.

FIG. 8 is an isometric perspective view showing multiple computing devices mounted inside a chassis of a computing system and an adjustable partition positioned at a first position, according to certain aspects of the present disclosure.

FIG. 9 is an isometric perspective view showing multiple computing devices mounted inside a chassis of a computing device and an adjustable partition positioned at a second position, according to certain aspects of the present disclosure.

FIG. 10 is a flowchart diagram showing a method for adjustably partitioning a chassis in a computing system by sliding an adjustable partition from a first position to a second position inside a chassis compartment of the chassis, according to certain aspects of the present disclosure.

FIG. 11 is a flowchart diagram showing an alternative method for adjustably partitioning a chassis in a computing system by use of an adjustable partition and a plurality of slots positioned on the chassis, according to certain aspects of the present disclosure.

FIG. 12 is a flowchart diagram showing another alternative method for adjustably partitioning a chassis in a computing system by use of an adjustable partition and a plurality of slots positioned on the chassis, according to certain aspects of the present disclosure.

### DETAILED DESCRIPTION

An adjustable partitioning device for a computing system is designed to efficiently partition a chassis compartment, e.g., an inside space, of a chassis of the computing system. The adjustable partitioning device includes an adjustable partition that is releasably secured inside the chassis compartment. The adjustable partition is configured to slide from a first position to a second position, or an intermediate position. Thus, by positioning at different positions, the adjustable partition efficiently separates the chassis compartment into sub-compartments that have different sizes. Accordingly, the chassis effectively accommodates various computing devices and/or components having different sizes.

More specifically, the chassis has the chassis compartment that is defined in part by a chassis cover and a chassis base. The chassis further has a plurality of slots disposed in either the chassis cover or the chassis base, or both. The adjustable partition of the adjustable partitioning device is movably mounted between the chassis cover and the chassis base to separate the chassis compartment into sub-compartments. Moreover, the adjustable partition has a plurality of hinges. The plurality of hinges is designed to slidably change position within respective ones of the plurality of slots when the adjustable partition is moved between a first position and a second position. Accordingly, each of the sub-compartments has a different size in the first position than in the second position.

A method is designed to flexibly partition a chassis of a computing system. Specifically, the method starts with disengaging one or more fasteners to release an adjustable partition from a chassis cover of the chassis. The chassis further has a chassis base. The chassis cover and the chassis base partially define a chassis compartment. The adjustable partition is movably mounted between the chassis cover and the chassis base to separate the chassis compartment into sub-compartments. Moreover, the method includes sliding the adjustable partition from a first position to a second position (or an intermediate position), thereby resulting in the sub-compartments each having a different size in the first position than in the second position. Further, the method secures the adjustable partition to the chassis cover using the one or more fasteners.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

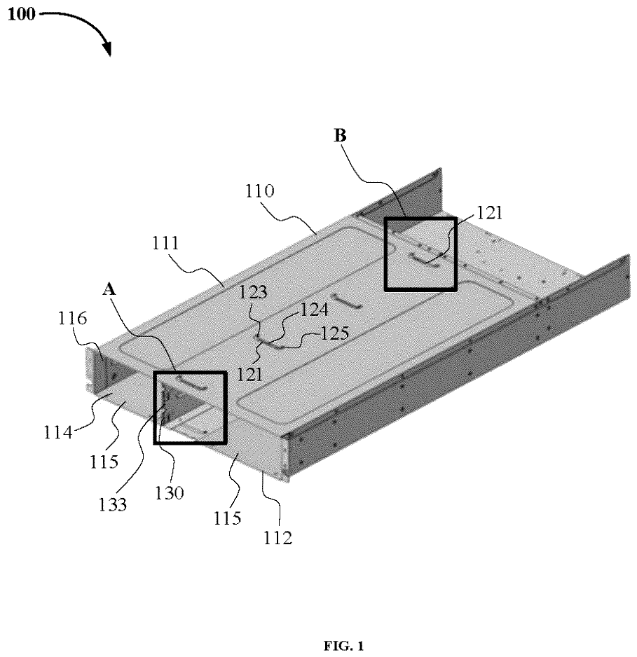

FIG. 1 illustrates a computing system 100 with a chassis and an adjustable partition installed inside the chassis and positioned at a first position. Specifically, the chassis 110 includes a chassis cover 111 and a chassis base 112. The chassis cover 111 is positioned on the chassis 110 opposite the chassis base 112. In some implementations, the chassis cover 111 and the chassis base 112 are oriented parallel to each other. Additionally, the chassis cover 111 and the chassis base 112 at least in part define a chassis compartment 114.

The adjustable partition 130 is movably mounted between the chassis cover 111 and the chassis base 112. As a divider, the adjustable partition 130 separates the chassis compartment 114 into sub-compartments 115. For example, the sub-compartments 115 include a first sub-compartment 116. Moreover, the adjustable partition 130 slides along the chassis base 112 and chassis cover 111 to change the width of the first sub-compartment 116 to receive a computing device or component with a different size than that of sub-compartment 116 before the change. As shown in FIG. 1, the adjustable partition 130 is positioned at a first position 133.

As shown in FIG. 1, the chassis 110 further includes a plurality of slots 121. The plurality of slots 121 is defined by one or more of the chassis cover 111 and the chassis base 112. Each of the plurality of slots includes a first end 123, a second end 125, and a channel 124. Both the first end 123 and the second end 125 are distally positioned on the channel 124.

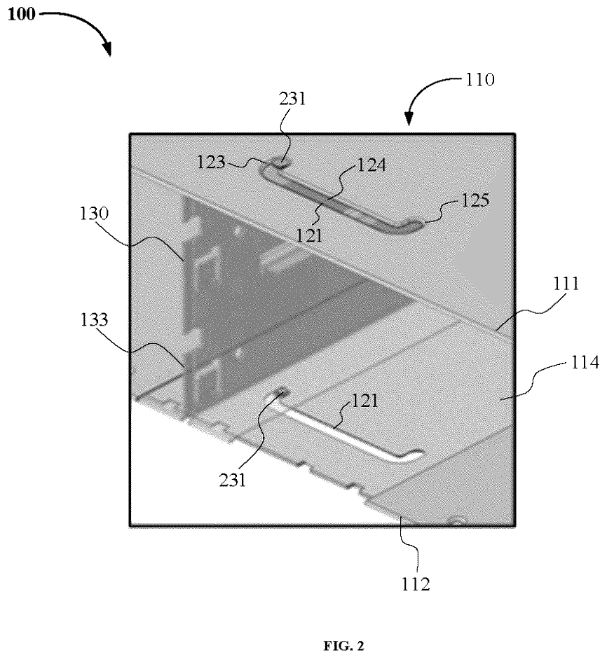

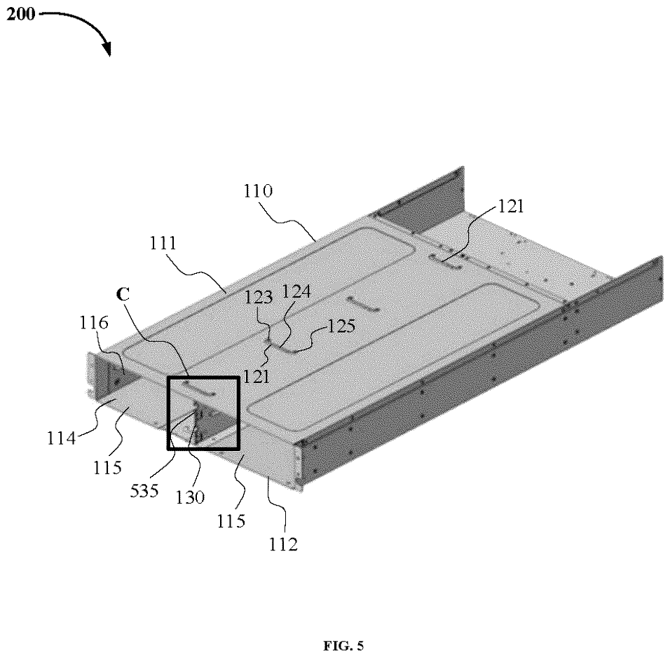

FIG. 2 illustrates the adjustable partition 130 and the plurality of slots 121 positioned on the chassis 110 by a sectional view of a section A indicated in FIG. 1. The adjustable partition 130 has a plurality of hinges 231. The plurality of hinges 231 is distally positioned on the adjustable partition 130. In some implementations, the plurality of hinges 231 is distributed on either one or both of two longitudinal sides of the adjustable partition 130, which are positioned in contact with the chassis cover 111 and the chassis base 112. Moreover, the plurality of hinges 231 is designed to slidably change position within the respective ones of the plurality of slots 121. For example, when the plurality of hinges 231 slides from the first end 123 along the channel 124 to the second end 125 of the respective ones of the plurality of slots 121, the adjustable partition 130 is moved from the first position 133 to a second position 535 (as shown in FIG. 5). Accordingly, the chassis compartment 114 is repartitioned.

As shown in FIG. 2, each of the plurality of hinges 231 is designed to slide between the first end 123 and the second end 125 within the channel 124. Additionally, each of the first end 123 and the second end 125 is oriented angularly relative to the channel 124. For example, at least one slot of the plurality of slots 121 is a U-shaped slot.

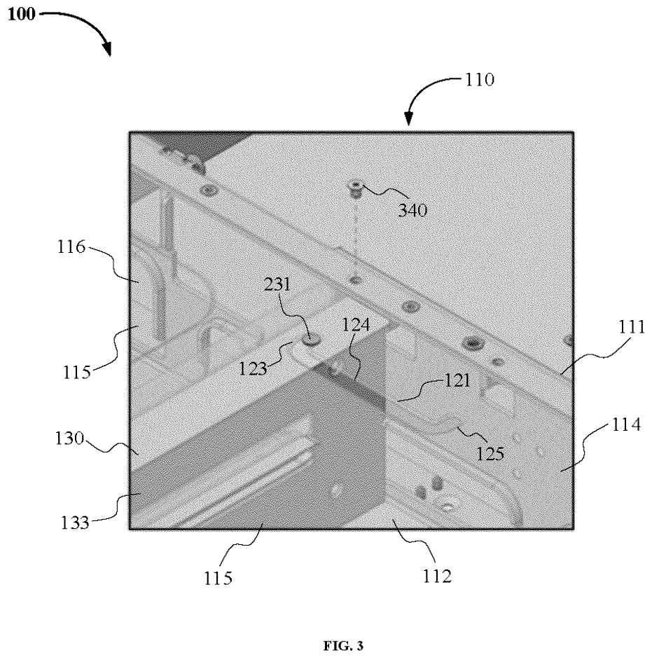

FIG. 3 illustrates how the adjustable partition 130 is releasably attached to the chassis cover 111 of the chassis 110 using one or more fasteners 340 by a sectional view of a section B indicated in FIG. 1. When fastened by the one or more fasteners 340, the adjustable partition 130 is secured to the chassis cover 111. For example, the adjustable partition 130 is secured to the chassis cover 111 and positioned at the first position 133 within the chassis compartment 114. Additionally, the adjustable partition 130 divides the chassis compartment 114 into the sub-compartments 115 that include the first sub-compartment 116. The plurality of hinges 231 of the adjustable partition 130 is positioned at the first end 123 of the respective slot of the plurality of slots 121.

When the one or more fasteners 340 are removed or released, the adjustable partition 130 is free to move or slide within the chassis compartment 114 and between the chassis cover 111 and the chassis base 112. For example, each of the plurality of hinges 231 slides from the first end 123 along the channel 124 to the second end 125 of the respective ones of the plurality of slots 121. The adjustable partition 130 is moved from the first position 133 to a second position 535 (as shown in FIG. 5). This example results in the sub-compartments 115 each having a different size in the first position 133 than in the second position 535. In some implementations, the one or more fasteners 430 include a screw, pushpin lock, quick release button, or any suitable fastener.

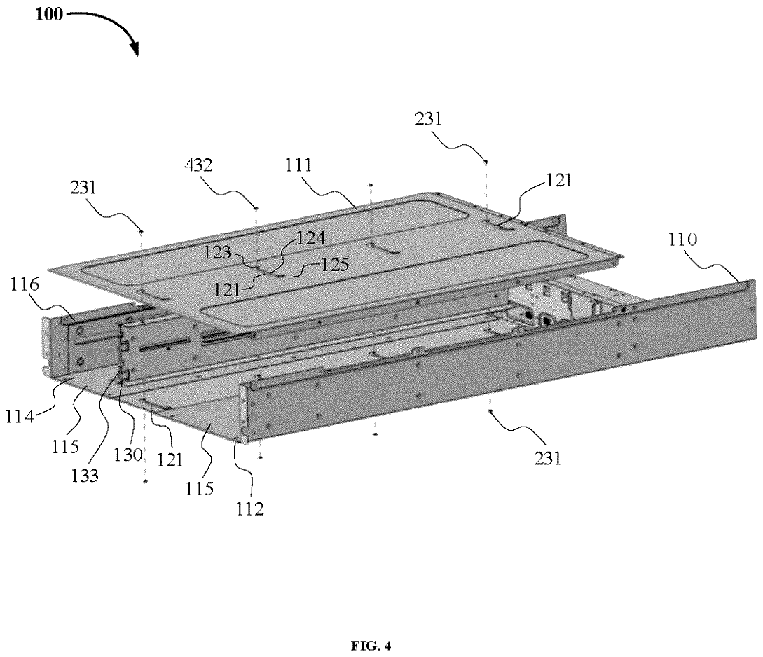

FIG. 4 illustrates the computing system 100 with the chassis 110 and the adjustable partition 130 installed inside the chassis and positioned at the first position 133, via an exploded perspective view. FIG. 4 is substantially the same as FIG. 1. Moreover, FIG. 4 is differentiated from FIG. 1 in that each of the plurality of hinges 231, for example, is a pushpin 432. Specifically, the pushpin 432 is terminally mounted to the adjustable partition 130. The pushpin 432 is positioned within the channel 124 and slidably moves between the first end 123 and the second end 125. At each of the first end 123 and the second end 125, the pushpin 432 locks onto the channel 124 of the respective slot of the plurality of slots 121. For example, the pushpin 432 locks onto the channel 124 by a compression force exerted on a top of the pushpin 432 towards the adjustable partition 130. Additionally, by a force in a reversed direction (pulling) exerted on the top of the pushpin 432, the pushpin 432 is unlocked and slidably moves within the channel 124 between the first end 123 and the second end 125, thus facilitating the adjustable partition 130 to change position between the first position 133 and the second position 535.

FIG. 5 illustrates a computing system 200 with the chassis 110 and the adjustable partition 130 installed inside the chassis compartment 114. The computer system 200 is substantially the same as the computing system 100 as shown in FIG. 1. Moreover, computing system 200 differentiates the computing system 100 in that the adjustable partition 130 is positioned at the second position 535. Additionally, due to the different position the adjustable partition 130 takes, the sub-compartments 115 each have different widths in the computing system 200 than in the computing system 100. Accordingly, the first sub-compartment 116 in the computing system 200 has a different, e.g., greater, width than that in the computing system 100.

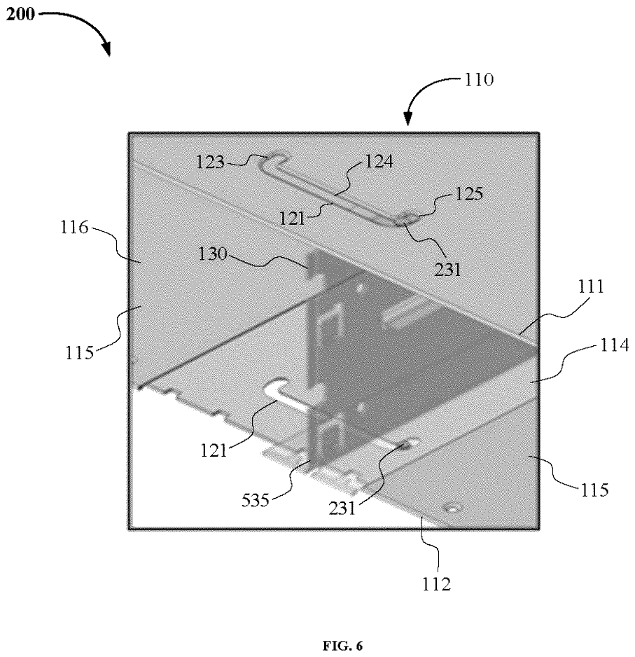

FIG. 6 illustrates the adjustable partition 130 installed inside the chassis 110 and positioned at the second position 535 in the computing system 200, via a sectional view of a section C indicated in FIG. 5. Specifically, the adjustable partition 130 is positioned inside the chassis 110 and between the chassis cover 111 and the chassis base 112. The adjustable partition 130, like a divider, separates the chassis compartment 114 into the sub-compartments 115. The sub-compartments 115 include the first sub-compartment 116. The adjustable partition 130 has the plurality of hinges 231 that is distally positioned on the adjustable partition 130. Additionally, each of the plurality of hinges 231 is designed to slide between the first end 123 and the second end 125, along the channel 124 of the respective one of the plurality of slots 121. For example, each of the plurality of hinges 231 is positioned at the second end 125. Thus, the adjustable partition 130 is positioned at the second position 535. Accordingly, the size of the first sub-compartment 116 is adjusted to be different than when the adjustable partition 130 is positioned at the first position 133, as shown in FIG. 1 and FIG. 2.

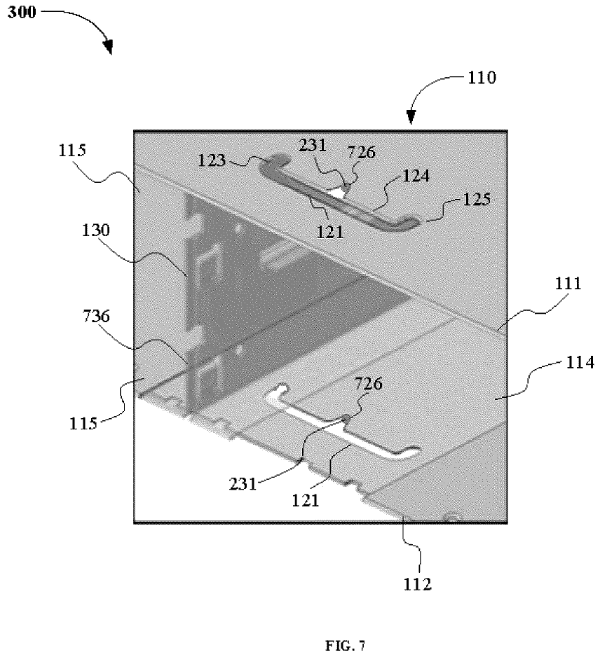

FIG. 7 illustrates a computing system 300 that is substantially similar to the computing systems 100 and 200. The computing system 300 is differentiated from the computing systems 100 and 200 in that the adjustable partition 130 is positioned at an intermediate position 736 instead of the first position 133 or the second position 535. Specifically, each channel 124 of the plurality of slots 121 has one or more intermediate ends 726 that are proximately positioned on the channel 124. Additionally, each hinge of the plurality of hinges 231 is slidably positioned on the one or more intermediate ends 726. The one or more intermediate ends 726 are positioned between the first end 123 and the second end 125. Each hinge of the plurality of hinges 231 is designed to slide either from the first end 123 or the second end 125 to the one or more intermediate ends 726 or vice versa. Thus, the adjustable partition 130 is moved to the intermediate position 736 by sliding each hinge of the plurality of hinges 231 to the one or more intermediate ends 726. Accordingly, the chassis compartment 114 of the chassis 100, defined at least in part by the chassis cover 111 and the chassis base 112, is divided into the sub-compartments 115 to receive and accommodate computing devices and/or components of specific widths.

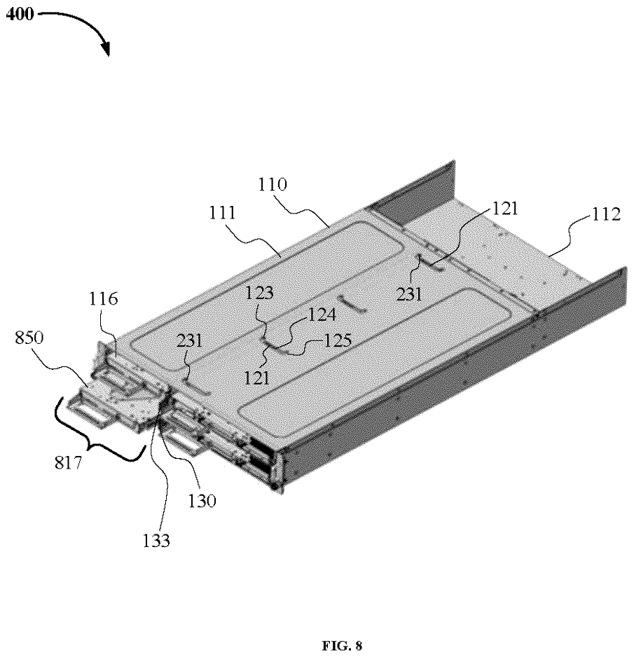

FIG. 8 illustrates a computing system 400 that includes multiple computing devices. The computing system 400 is substantially similar to the computing system 100 shown in FIG. 1. Both the computer system 400 and the computing system 100 have the same components: the chassis 110, chassis cover 111, chassis base 112, the plurality of slots 121, the first end 123, the channel 124, the second end 125, the adjustable partition 130, the first position 133, the plurality of hinges 231, and the first sub-compartment 116. The computing system 400 is differentiated from the computing system 100 in that the computing system 400 includes multiple computing devices, e.g., a first computing device 850, and a first size 817 of the first sub-compartment 116. Specifically, the first position 133 of the adjustable partition 130 defines the first sub-compartment 116. The first size 817 of the first sub-compartment 116 is designed to allow the first sub-compartment 116 to receive the first computing device 850 with the matching size of the first size 817.

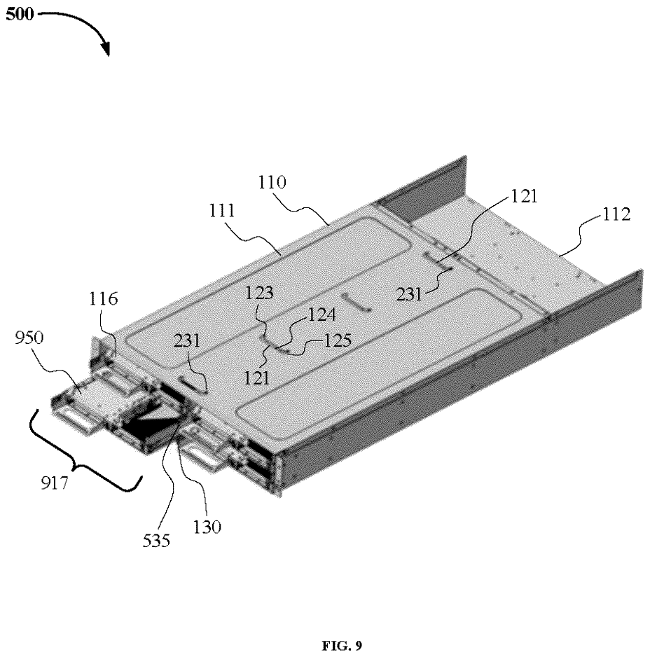

FIG. 9 illustrates how the computing system 500 has multiple computing devices that are different from those in the computing system 400, e.g., a second computing device 950 instead of the first computing device 850, as shown in FIG. 8. The computing system 500 is substantially similar to the computing system 400 but different in that the adjustable partition 130 is positioned at the second position 535. Thus, the first sub-compartment 116 has a different size, e.g., a second size 917, that matches a size of the second computing device 950.

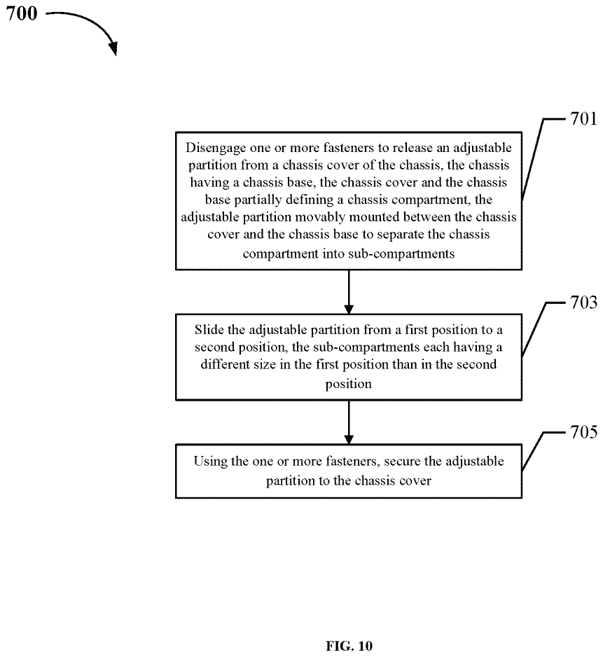

FIG. 10 shows a method 700 for flexibly partitioning a chassis of a computing system, e.g., the computing systems 100, 200, 300, 400, and 500 (described above). Specifically, the method 700 includes disengaging one or more fasteners to release an adjustable partition from a chassis cover of the chassis (Step 701). The chassis further has a chassis base. The chassis cover and the chassis base partially define a chassis compartment. The adjustable partition is movably mounted between the chassis cover and the chassis base to separate the chassis compartment into sub-compartments. Moreover, the method 700 includes sliding the adjustable partition from a first position to a second position (Step 703). Here, the sub-compartments each have a different size in the first position than in the second position. Further, the method 700 includes securing the adjustable partition to the chassis cover using the one or more fasteners (Step 705).

In Step 701 and Step 705 of the method 700 for some implementations, the one or more fasteners include a screw, pushpin lock, quick release button, or any suitable fastener. The one or more fasteners secure the adjustable partition during computing operations of the computing system. Moreover, the one or more fasteners allow effective accommodations of components with variable sizes in the chassis compartment without disassembling the chassis of the computing system. With the ability of slidably moving between the first position and the second position, the adjustable partition facilitates efficient partitioning of the chassis compartment based on the need for variable widths of the sub-compartments.

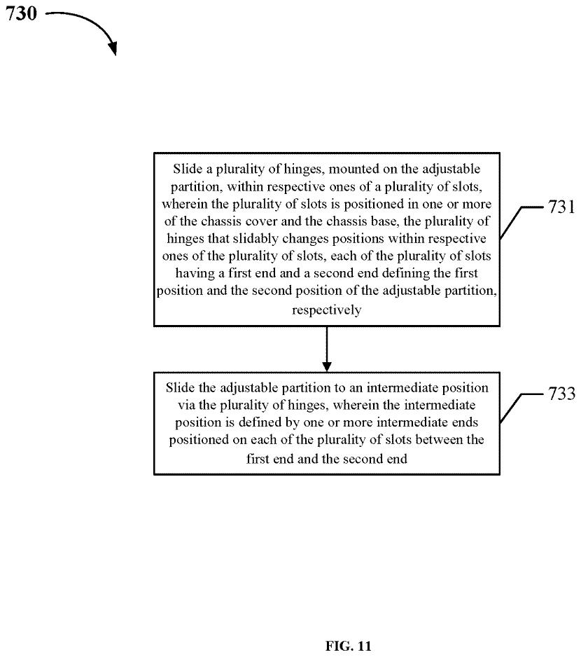

FIG. 11 shows an alternative method 730 for adjustably partitioning the chassis in the computing system by use of the adjustable partition and a plurality of slots positioned on the chassis. Specifically, the method 730 includes sliding a plurality of hinges, mounted on the adjustable partition, within respective ones of a plurality of slots (Step 731). In this method, the plurality of slots is positioned in one or more of the chassis cover and the chassis base. The plurality of hinges slidably changes positions within respective ones of the plurality of slots. Moreover, each of the plurality of slots has a first end and a second end defining the first position and the second position of the adjustable partition, respectively.

As shown in FIG. 11, the method 730 further includes sliding the adjustable partition to an intermediate position via the plurality of hinges (Step 733). The intermediate position is defined by the one or more intermediate ends positioned on each of the plurality of slots between the first end and the second end.

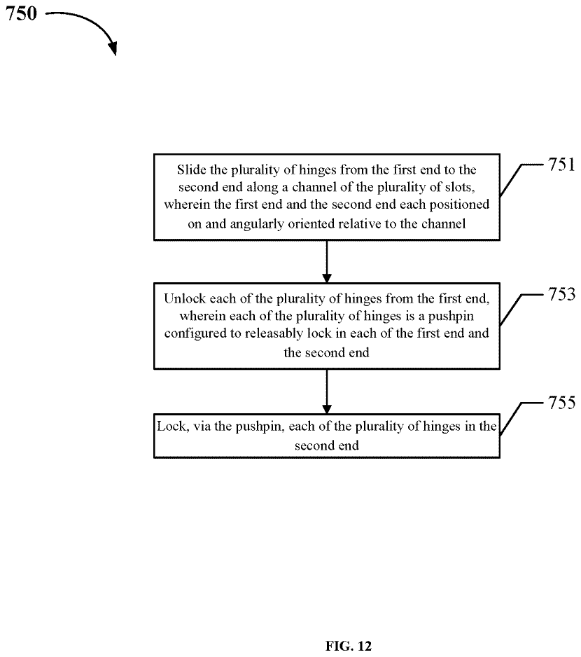

FIG. 12 shows another alternative method 750 for adjustably partitioning the chassis in the computing system by use of the adjustable partition and a plurality of slots positioned on the chassis. Specifically, the method 750 includes sliding the plurality of hinges from the first end to the second end along a channel of the plurality of slots (Step 751). The first end and the second end each are positioned on and angularly oriented relative to the channel.

Additionally, the method 750 includes unlocking each of the plurality of hinges from the first end (Step 753). Each of the plurality of hinges is a pushpin configured to releasably lock in each of the first end and the second end.

Further, the method 750 includes locking, via the pushpin, each of the plurality of hinges in the second end (Step 755).

What is claimed is:

1. An adjustable partitioning device for a computing system, the adjustable partitioning device comprising:
a chassis having a chassis compartment defined in part by a chassis cover and a chassis base, the chassis further having a plurality of slots in one or more of the chassis cover and the chassis base; and
an adjustable partition movably mounted between the chassis cover and the chassis base to separate the chassis compartment into sub-compartments, the adjustable partition having a plurality of hinges that slidably changes position within respective ones of the plurality of slots when the adjustable partition is moved between a first position and a second position, the sub-compartments each having a different size in the first position than in the second position.

2. The adjustable partitioning device of claim 1, wherein each slot of the plurality of slots is defined by a channel extending between a first end and a second end, the first end corresponding to the first position and the second end corresponding to the second position.

3. The adjustable partitioning device of claim 2, wherein each hinge of the plurality of hinges is configured to slide between the first end and the second end within the channel.

4. The adjustable partitioning device of claim 2, wherein each of the first end and the second end is oriented angularly relative to the channel.

5. The adjustable partitioning device of claim 2, wherein at least one slot of the plurality of slots has a U-shape.

6. The adjustable partitioning device of claim 2, wherein the channel has an intermediate end that is proximately positioned thereon, each hinge of the plurality of hinges being slidably positioned on the intermediate end.

7. The adjustable partitioning device of claim 2, wherein each of the plurality of hinges is a pushpin that is configured to releasably lock in each of the first end and the second end.

8. The adjustable partitioning device of claim 1, wherein the adjustable partition is releasably secured to the chassis cover via one or more fasteners.

9. A computing system comprising:
a chassis having a plurality of slots and a chassis compartment, the chassis compartment being divided into sub-compartments that include a first sub-compartment, the first sub-compartment having a first size in a first position to receive a first computing device; and
an adjustable partition movably mounted within the chassis compartment as a divider between the sub-compartments, the adjustable partition having a plurality of hinges that slidably mount to and change position within respective ones of the plurality of slots, the adjustable partition being movable between the first position and a second position, the first sub-compartment having a second size in the second position to receive a second computing device that has a different size than the first computing device.

10. The computing system of claim 9, wherein the chassis includes a chassis cover and a chassis base, and wherein the chassis cover and the chassis base at least in part define the chassis compartment.

11. The computing system of claim 10, wherein the plurality of slots is positioned on one or more of the chassis cover and the chassis base.

12. The computing system of claim 9, wherein each slot of the plurality of slots has a channel extending between a first end and a second end, the first end corresponding to the first position and the second end corresponding to the second position.

13. The computing system of claim 12, wherein each hinge of the plurality of hinges is configured to slide between the first end and the second end within the channel.

14. The adjustable partitioning system of claim 12, wherein the channel has an intermediate end that are proximately positioned thereon, each of the plurality of hinges slidably positioned on the intermediate end.

15. A method of flexibly partitioning a chassis of a computing system, comprising:
disengaging one or more fasteners to release an adjustable partition from a chassis cover of the chassis, the chassis having a chassis base, the chassis cover and the chassis base partially defining a chassis compartment, the adjustable partition movably mounted between the chassis cover and the chassis base to separate the chassis compartment into sub-compartments;
sliding the adjustable partition from a first position to a second position, the sub-compartments each having a different size in the first position than in the second position; and
using the one or more fasteners, securing the adjustable partition to the chassis cover.

16. The method of claim 15, further comprising:
sliding a plurality of hinges, mounted on the adjustable partition, within respective ones of a plurality of slots, wherein the plurality of slots is positioned in one or more of the chassis cover and the chassis base, the plurality of hinges that slidably changes positions within the respective ones of the plurality of slots, each of the plurality of slots having a first end and a second end defining the first position and the second position of the adjustable partition, respectively.

17. The method of claim 16, further comprising:
sliding the adjustable partition to an intermediate position via the plurality of hinges, wherein the intermediate position is defined by one or more intermediate ends positioned on each of the plurality of slots between the first end and the second end.

18. The method of claim 16, further comprising:
sliding the plurality of hinges from the first end to the second end along a channel of the plurality of slots, wherein the first end and the second end each positioned on and angularly oriented relative to the channel.

19. The method of claim 18, further comprising:
unlocking each of the plurality of hinges from the first end, wherein each of the plurality of hinges is a pushpin configured to releasably lock in each of the first end and the second end.

20. The method of claim 19, further comprising:
locking, via the pushpin, each of the plurality of hinges in the second end.
